(19) United States
(12) Patent Application Publication
(10) Pub. No.: US 2015/0262932 A1
(43) Pub. Date: Sep. 17, 2015

(54) NONVOLATILE SEMICONDUCTOR MEMORY DEVICE AND METHOD FOR MANUFACTURING SAME

(71) Applicant: Kabushiki Kaisha Toshiba, Minato-ku (JP)

(72) Inventors: Osamu YAMANE, Yokohama-shi (JP); Tadashi IGUCHI, Yokkaichi-shi (JP); Hiromitsu MASHITA, Yokohama-shi (JP)

(73) Assignee: Kabushiki Kaisha Toshiba, Minato-ku (JP)

(21) Appl. No.: 14/302,976

(22) Filed: Jun. 12, 2014

Related U.S. Application Data
(60) Provisional application No. 61/952,449, filed on Mar. 13, 2014.

(51) Int. Cl. H01L 23/528; H01L 21/768; H01L 21/285; H01L 27/115; H01L 29/49

(52) U.S. Cl. CPC H01L 23/528; H01L 27/11582; H01L 29/4916; H01L 21/28562; H01L 27/11556; H01L 21/76879; H01L 27/11519; H01L 27/11565

(57) ABSTRACT

According to one embodiment, a nonvolatile semiconductor memory device includes: a semiconductor substrate; a multilayer interconnection structure unit; a stacked body; a channel body layer; a memory film; a contact electrode. The multilayer interconnection structure unit is provided on the semiconductor substrate, and the multilayer interconnection structure unit has interconnections. The stacked body is provided on the multilayer interconnection structure unit, and each of electrode layers and each of first insulating layers are alternately arranged in the stacked body. The channel body layer extends in the stacked body in a stacking direction of the stacked body. The memory film is provided between the channel body layer and each of the electrode layers. And the contact electrode extends in the stacked body in the stacking direction, and the contact electrode electrically connects any one of the electrode layers and any one of the interconnection layers.

### CROSS-REFERENCE TO RELATED APPLICATIONS

This application is based upon and claims the benefit of priority from U.S. Provisional Patent Application 61/952,449 filed on Mar. 13, 2014; the entire contents of which are incorporated herein by reference.

### FIELD

Embodiments described herein relate generally to a nonvolatile semiconductor device and a method for manufacturing same.

### BACKGROUND

In a NAND type nonvolatile semiconductor memory device, a contact electrode which are electrically connected to each of word lines of a memory cell array is extended upward to an upper side of the memory cell array, and the contact electrode is, for example, connected to upper interconnections. However, as the number of stacked layers in the memory cell array is increased, the number of the contact electrode connected to each word line or the number of upper interconnections is increased. Therefore, a pitch of the contact electrodes and a pitch of the upper interconnections are reduced, so that a micro-patterning technique is needed when these components are processed. However, as the number of stacked layers in the memory cell array is increased, a lithography margin is reduced in the micro-patterning technique. Furthermore, the patterning is getting to be difficult.

### BRIEF DESCRIPTION OF THE DRAWINGS

FIG. 1 is a schematic perspective view showing an overview of a memory cell array unit of a nonvolatile semiconductor memory device according to an embodiment;

FIG. 2 is a schematic cross-sectional view showing a memory cell array unit, a multilayer interconnection structure unit under the memory cell array unit, and a semiconductor substrate under the multilayer interconnection structure unit in the nonvolatile semiconductor memory device according to the embodiment;

FIG. 3A is a schematic cross-sectional view showing the nonvolatile semiconductor memory device according to the embodiment and FIG. 3B is a schematic plan view showing the nonvolatile semiconductor memory device according to the embodiment;

FIG. 4A to FIG. 5C are schematic cross-sectional views showing processes of manufacturing the nonvolatile semiconductor memory device according to the embodiment;

FIG. 6A and FIG. 6B are schematic cross-sectional views showing a nonvolatile semiconductor memory device according to the variation of the embodiment; and

FIG. 7A is a schematic plan view showing layout of interconnections according to a reference example, and FIG. 7B is a schematic plan view showing layout of interconnections according to the embodiment.

### DETAILED DESCRIPTION

According to one embodiment, a nonvolatile semiconductor memory device includes: a semiconductor substrate; a multilayer interconnection structure unit; a stacked body; a channel body layer; a memory film; a contact electrode. The multilayer interconnection structure unit is provided on the semiconductor substrate, and the multilayer interconnection structure unit has a plurality of interconnections. The stacked body is provided on the multilayer interconnection structure unit, and each of a plurality of electrode layers and each of a plurality of first insulating layers are alternately arranged in the stacked body. The channel body layer extends in the stacked body in a stacking direction of the stacked body. The memory film is provided between the channel body layer and each of the electrode layers. And the contact electrode extends in the stacked body in the stacking direction, and the contact electrode electrically connects any one of the electrode layers and any one of the interconnection layers.

Hereinafter, embodiments of the invention will be described with reference to the drawings. In the description hereinafter, the same portions are denoted by the same reference numerals, and the description of the component described once is appropriately omitted. Each figure is a schematic diagram for description of the invention and for the better understanding of the invention. Although the shape, dimension, ratio, and the like are different from those of the actual cases in each figure, the design thereof can be appropriately changed with reference to the description hereinafter and known techniques.

First, an overview of a nonvolatile semiconductor memory device will be described.

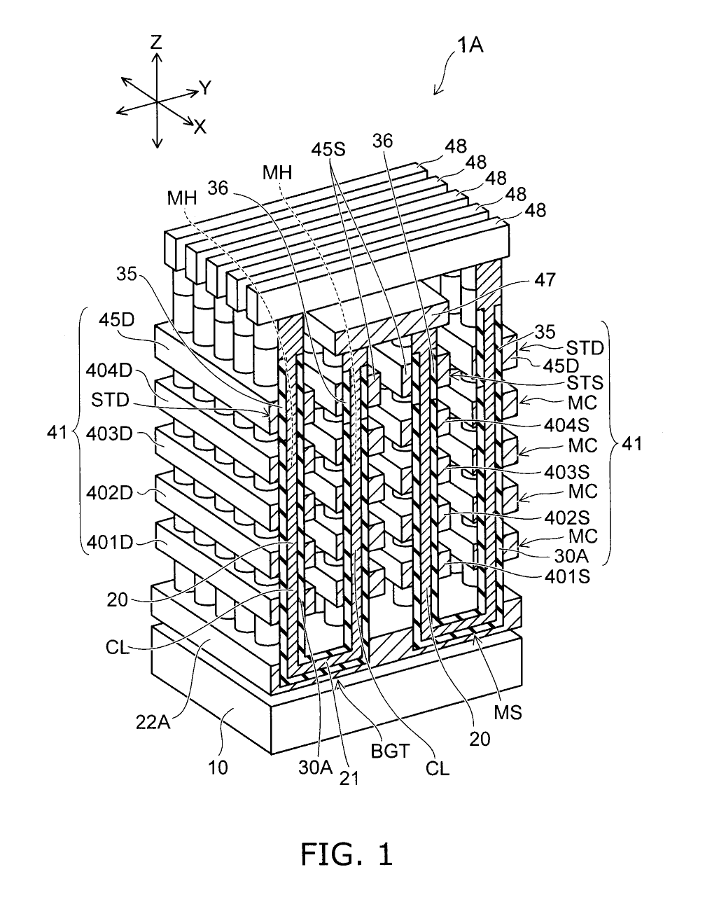

FIG. 1 is a schematic perspective view showing an overview of a memory cell array unit of a nonvolatile semiconductor memory device according to the embodiment.

In FIG. 1, for clarifying the figure, insulating portions excluding insulating films formed on inner walls of memory holes MH are omitted in illustration.

In FIG. 1, for the convenience of description, an X-Y-Z rectangular coordinate system is introduced. In the coordinate system, two directions which are parallel to a major surface of a semiconductor substrate 10 and are perpendicular to each other are defined as an X-direction and a Y-direction, and a direction which is perpendicular to the X-direction and the Y-direction is defined as a Z-direction.

A nonvolatile semiconductor memory device 1 is a NAND type nonvolatile memory on which data erasing and writing can be performed electrically and flexibly and memory content is retained even if the power is off. The nonvolatile semiconductor memory device 1 illustrated in FIG. 1 is generally referred to as a bit cost scalable (BiCS) flash memory.

In the nonvolatile semiconductor memory device 1, a backgate 22A is provided via an insulating layer (not shown) on the semiconductor substrate 10. The semiconductor substrate 10 and the insulating layer are collectively called an underlaying layer. The semiconductor substrate 10 is, for example, a silicon substrate. Besides, active elements such as transistors and passive elements such as resistors and capacitor may be provided in the semiconductor substrate 10. The backgate 22A is, for example, a silicon (Si) containing layer including impurity elements.

In FIG. 1, as an example, drain-side electrode layers 401D, 402D, 403D, and 404D and source-side electrode layers 401S, 402S, 403S, and 404S are stacked on the backgate 22A. In addition, insulating layers (not shown) are provided between upper and lower electrode layers.

The electrode layer 401D and the electrode layer 401S are provided on the same layer and are the electrode layers as the first layers from the bottom. The electrode layer 402D and the electrode layer 402S are provided on the same layer and are the electrode layers as the second layers from the bottom. The electrode layer 403D and the electrode layer 403S are provided on the same layer and are the electrode layers as the third layers from the bottom. The electrode layer 404D and the electrode layer 404S are provided on the same layer and are the electrode layers as the fourth layers from the bottom.

The electrode layer 401D and the electrode layer 401S are separated in the Y-direction. The electrode layer 402D and the electrode layer 402S are separated in the Y-direction. The electrode layer 403D and the electrode layer 403S are separated in the Y-direction. The electrode layer 404D and the electrode layer 404S are separated in the Y-direction.

The insulating layers (not shown) are provided between the electrode layer 401D and the electrode layer 401S, between the electrode layer 402D and the electrode layer 402S, between the electrode layer 403D and the electrode layer 403S, and between the electrode layer 404D and the electrode layer 404S.

The electrode layers 401D, 402D, 403D, and 404D are provided between the backgate 22A and a drain-side select gate electrode 45D. The electrode layers 401S, 402S, 403S, and 404S are provided between the backgate 22A and a source-side select gate electrode 45S.

The number of layers of the electrode layers 401D, 402D, 403D, 404D, 401S, 402S, 403S, and 404S is arbitrary and is not limited to four layers illustrated in FIG. 1. In addition, in the embodiment, in some cases, the electrode layers 401D, 402D, 403D, 404D, 401S, 402S, 403S, and 404S are collectively and simply referred to as electrode layers 40. An electrode layer WL is, for example, a conductive silicon-containing layer including impurity elements such as boron (B).

The drain-side select gate electrode 45D is provided on the electrode layer 404D via an insulating layer (not shown). The drain-side select gate electrode 45D is, for example, a conductive silicon-containing layer including impurities. The source-side select gate electrode 45S is provided on the electrode layer 404S via an insulating layer (not shown). The source-side select gate electrode 45S is, for example, a conductive silicon-containing layer including impurities.

The drain-side select gate electrode 45D and the source-side select gate electrode 45S are separated in the Y-direction. In addition, the drain-side select gate electrode 45D and the source-side select gate electrode 45S may also be simply referred to as a select gate electrode 45 without distinction.

A source line 47 is provided on the source-side select gate electrode 45S via an insulating layer (not shown). The source line 47 is connected to one of a pair of channel body layers 20. The source line 47 is a metal layer or a conductive silicon-containing layer including impurities.

A plurality of bit lines 48 are provided on the drain-side select gate electrode 45D and the source line 47 via an insulating layer (not shown). The bit lines 48 are connected to the other of the pair of the channel body layers 20. The bit lines 48 extend in the Y-direction.

A plurality of U-shaped memory holes MH are formed in the backgate 22A and in a stacked body 41 on the backgate 22A. The memory holes MH are through-holes before the channel body layers 20 and memory films 30A are formed. For example, a hole is formed in the electrode layers 401D to 404D and in the drain-side select gate electrode 45D, the hole penetrates (pierces) the layers and the electrode, and the hole extends in the Z-direction. A hole is formed in the electrode layers 401S and 404S and in the source-side select gate electrode 45S, the hole penetrates the layers and the electrode, and the hole extends in the Z-direction. A pair of the holes extending in the Z-direction is connected through a recess portion (space portion) formed in the backgate 22A so as to constitute the U-shaped memory hole MH.

The channel body layer 20 is provided in a U shape inside the memory hole MH. The channel body layer 20 is, for example, a silicon-containing layer. A memory film 30A is provided between the channel body layer 20 and the inner wall of the memory hole MH.

A gate insulating film 35 is provided between the channel body layer 20 and the drain-side select gate electrode 45D. A gate insulating film 36 is provided between the channel body layer 20 and the source-side select gate electrode 45S.

The drain-side select gate electrode 45D, the channel body layers 20, and the gate insulating film 35 provided therebetween constitute a drain-side selection transistor STD. The channel body layer 20 above the drain-side selection transistor STD is connected to the bit lines 48.

The source-side select gate electrode 45S, the channel body layers 20 and the gate insulating film 36 provided therebetween constitute a source-side selection transistor STS. The channel body layers 20 above the source-side selection transistor STS is connected to the source line 47.

The backgate 22A and the channel body layer 20 and the memory film 30A which are provided in the backgate 22A constitute a backgate transistor BGT.

A plurality of memory cells MC are provided between the drain-side selection transistor STD and the backgate transistor BGT. The electrode layers 404D to 401D function as control gates. Similarly, a plurality of memory cells MC are also provided between the backgate transistor BGT and the source-side selection transistor STS. The electrode layers 401S to 404S function as control gates.

The plurality of memory cells MC, the drain-side selection transistor STD, the backgate transistor BGT, and the source-side selection transistor STS are connected in series through the channel body layer so as to constitute one U-shaped memory string MS.

One memory string MS has a pair of column portions CL which extend in the stacking direction of the stacked body 41 including the plurality of electrode layers and a connection portion 21 which is buried in the backgate 22A to connect a pair of the column portions CL. The plurality of memory strings MS are provided in the X-direction and the Y-direction, and the plurality of memory cells are three-dimensionally provided in the X-direction, the Y-direction, and the Z-direction.

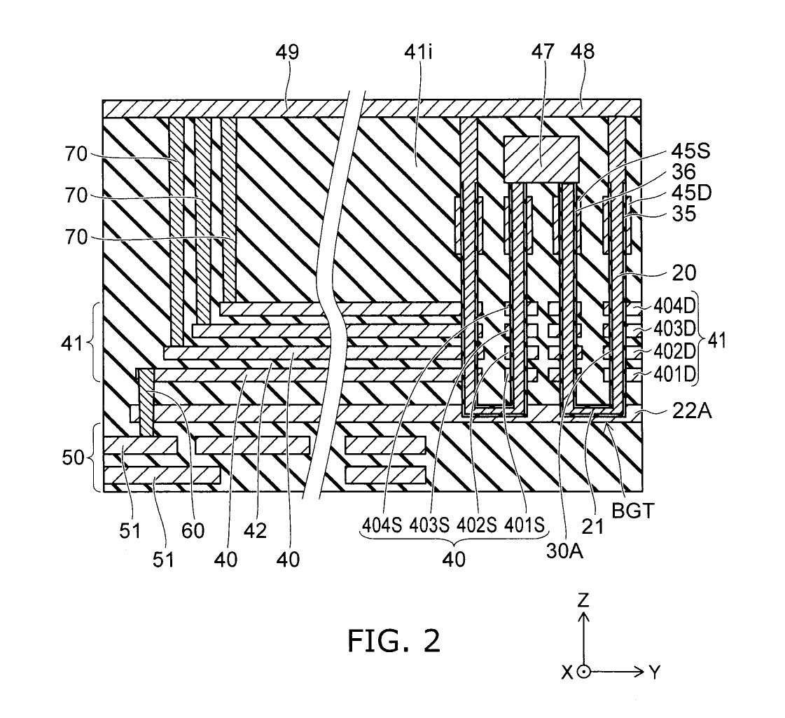

FIG. 2 is a schematic cross-sectional view showing a memory cell array unit, a multilayer interconnection structure unit under the memory cell array unit, and a semiconductor substrate under the multilayer interconnection structure unit in the nonvolatile semiconductor memory device according to the embodiment.

Herein, FIG. 2 shows a cross section in a Y-Z plane.

In the nonvolatile semiconductor memory device 1, a multilayer interconnection structure unit 50 including a plurality of interconnection layers 51 are provided on the upper side of the semiconductor substrate 10. Interlayer insulating films 50i are provided above and below each interconnection layer. In addition, the semiconductor substrate 10 shown in FIG. 1 is provided on the lower side of the multilayer interconnection structure unit 50, and a plurality of MOS transistors as semiconductor elements are disposed on the surface layer of the semiconductor substrate.

The stacked body 41 where each of the plurality of electrode layers 40 and each of the plurality of insulating layers 42 are alternately arranged is provided on the multilayer interconnection structure unit 50. The channel body layer 20 extends in the stacking direction (Z-direction) in the stacked body 41. The memory film 30A is provided between each of the plurality of electrode layers 40 and channel body layer 20. An interlayer insulating film 41i is provided on the stacked body 41.

In the nonvolatile semiconductor memory device 1, in the figure, each of contact electrodes 70 is electrically connected to one of the plurality of electrode layers 40 and is extended upward from the electrode layer 40 to the upper portion of the nonvolatile semiconductor memory device 1. The upper end of the contact electrode 70 is connected to a interconnection 49 disposed on the upper side of the stacked body 41.

In addition, the nonvolatile semiconductor memory device 1 includes contact electrodes 60. Each of contact electrodes 60 electrically connects any one of the plurality of electrode layers 40 and any one of the plurality of interconnection layers 51. The contact electrode 60 extends in the stacking direction in the stacked body 41. The lower end of the contact electrode 60 is, for example, in contact with the interconnection layer 51. Herein, for example, the interconnection layer 51 connected to the contact electrode 60 can be used as a substitute for the interconnection 49.

The contact electrode includes polysilicon, tungsten, molybdenum, titanium, titanium nitride, or the like.

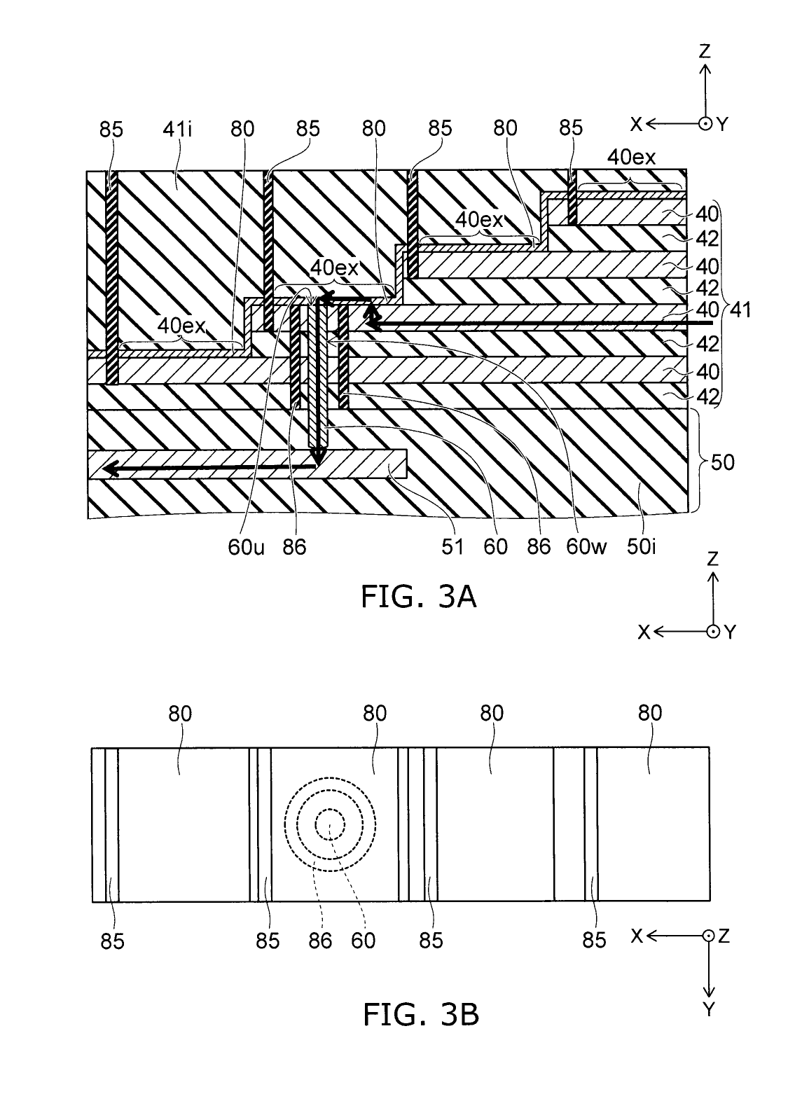

FIG. 3A is a schematic cross-sectional view showing the nonvolatile semiconductor memory device according to the embodiment, and FIG. 3B is a schematic plan view showing the nonvolatile semiconductor memory device according to the embodiment.

In FIGS. 3A and 3B, the vicinity of the multilayer interconnection structure unit 50 and the contact electrode 60 is shown in an enlarged diagram.

Each of the plurality of electrode layers 40 has an extension portion 40ex. Any of the plurality of electrode layers 40 does not exist above the extension portions 40ex. In other words, the plurality of electrode layers 40 forms a staircase pattern.

A conductive film 80 provided on the extension portion 40ex is in contact with an upper end 60u of the contact electrode 60. The conductive film 80 includes conductive amorphous silicon, tungsten, or the like. In other words, the contact electrode 60 is electrically connected to any one of the plurality of electrode layers 40 through the conductive film 80. In addition, as the plurality of electrode layers 40 is seen from the upper surface, a conductive film 80 provided on an extension portion 40ex of any one of the plurality of electrode layers 40 and another conductive film 80 provided on another extension portion 40ex adjacent to the extension portion 40ex are insulated each other by an insulating layer 85.

Herein, an insulating layer 86 is provided between a side portion 60w of the contact electrode 60 and the stacked body 41. The insulating layer 86 surrounds the contact electrode 60. The insulating layer 86 has a tubular shape. Accordingly, insulation between the contact electrode 60 and the stacked body 41 is maintained. In addition, the contact electrode 60 and the insulating layer 86 are not in contact with each other. A portion of the stacked body 41 is interposed between the contact electrode 60 and the insulating layer 86. In addition, as seen from the upper surface, the insulating layer 86 may have a polygonal shape besides a circular shape.

According to this structure, for example, current of the electrode layer 40 electrically connected to the contact electrode 60 flows into the interconnection layer 51 through the conductive film 80 and the contact electrode 60 (refer to the arrow). In other words, signal can be transmitted and received through this current path.

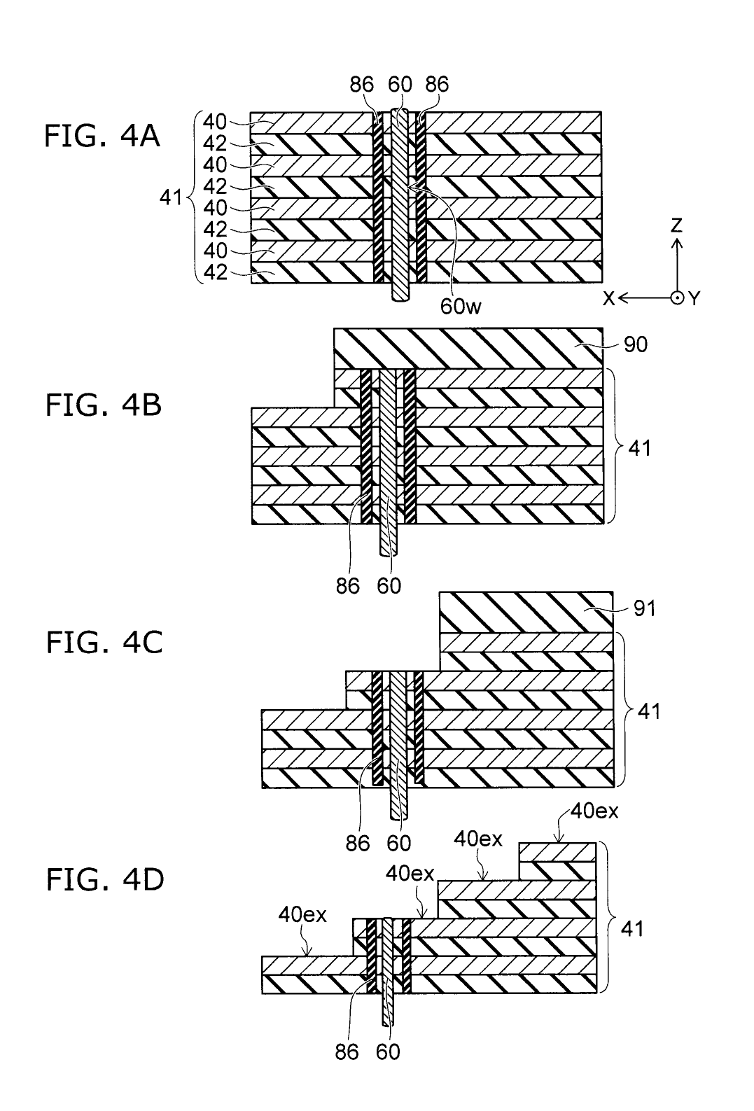

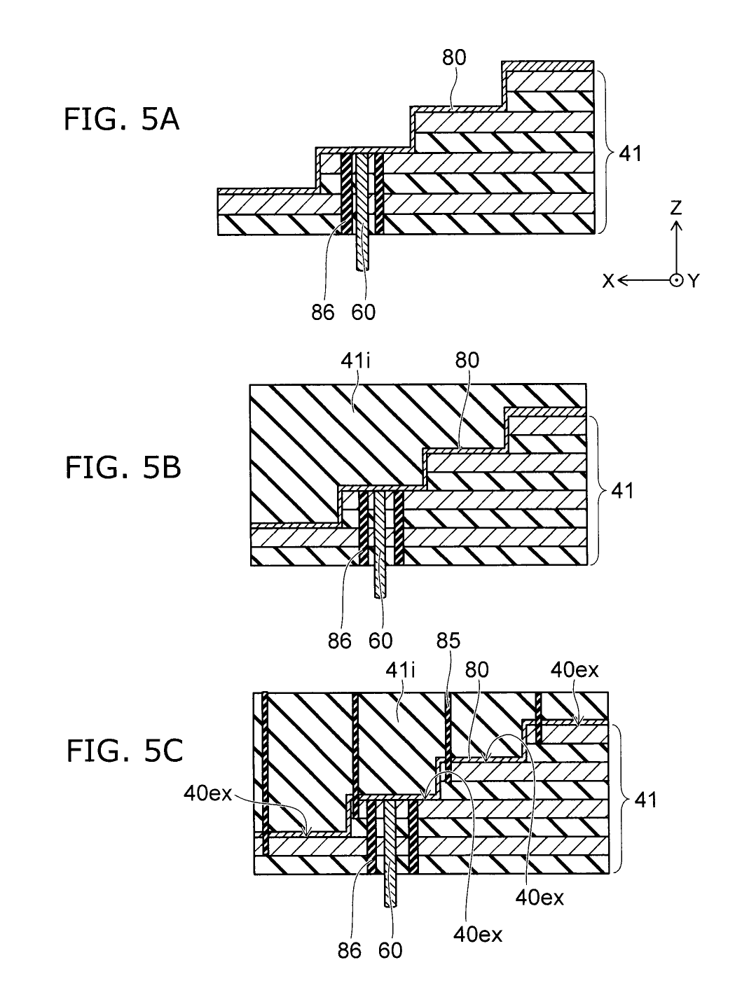

FIG. 4A to FIG. 5C are schematic cross-sectional views showing processes of manufacturing the nonvolatile semiconductor memory device according to the embodiment.

First, as shown in FIG. 4A, the stacked body 41 is prepared. Each of the plurality of electrode layers 40 and each of the plurality of insulating layers 42 are alternately arranged in the stacked body 41 As illustrated in FIG. 1 and the like, the semiconductor substrate 10 and the multilayer interconnection structure unit 50 provided on the semiconductor substrate 10 are disposed below of the stacked body 41.

Subsequently, the contact electrode 60 is formed to penetrate the stacked body 41 in the stacking direction (Z-direction) of the stacked body 41. The contact electrode 60 is to be electrically connected to any one of the plurality of electrode layers 40. In addition, the insulating layer 86 is formed between the side portion 60w of the contact electrode 60 and the stacked body 41.

Next, as shown in FIG. 4B to FIG. 4D, the stacked body is formed into a staircase pattern by performing the processes. For example, as shown in FIG. 4B, a mask layer 90 for exposing a portion of the uppermost electrode layer 40 is formed, and the exposed uppermost electrode layer 40 and the insulating layer 42 just below the exposed electrode layer 40 are processed by reactive ion etching (RIE).

Subsequently, the portion of the electrode layer 40 which is first processed by the RIE is not covered by a mask layer 91. The mask layer 91 is formed for exposing a portion of the uppermost electrode layer 40. And the exposed uppermost electrode layer 40 and the insulating layer 42 just below the exposed electrode layer 40 are processed by the RIE. In the this step, since the mask layer 91 is not provided on the portion of the electrode layer 40 which is first processed, the portion of the electrode layer 40 which is first processed is processed so as to be further deeply by the RIE.

By repeating such a RIE process, the stacked body 41 is processed into a staircase pattern. In addition, in a case where the material of the contact electrode 60 is polysilicon, since materials of the contact electrode 60 and the electrode layer 40 are substantially same. Thereby, no difference between etching rates thereof does not occur. Furthermore, the material of the insulating layer 86 is also the same as that of the insulating layer 42. Therefore, the heights of the contact electrode 60 and insulating layer 86 and the height of the extension portion 40ex where the contact electrode 60 is positioned are aligned.

In this manner, the structure where the plurality of electrode layers 40 each have the extension portion 40ex can be obtained. Any of the plurality of electrode layers 40 does not exist on the upper side of the extension portions 40ex.

Next, as shown in FIG. 5A, the conductive film 80 is formed on the stacked body 41 having a staircase pattern.

Next, as shown in FIG. 5B, the interlayer insulating film 41i is formed on the stacked body 41 having a staircase pattern via the conductive film 80.

Next, as shown in FIG. 5C, the insulating layer 85 is formed. The insulating layer 85 divides the conductive film 80 provided on the adjacent extension portions 40ex. Accordingly, the conductive film 80 is formed on the extension portion 40ex where the contact electrode 60 is positioned. In other words, the structure where the upper end 60u of the contact electrode 60 is in contact with the conductive film 80 is obtained.

A variation of the embodiment will be described.

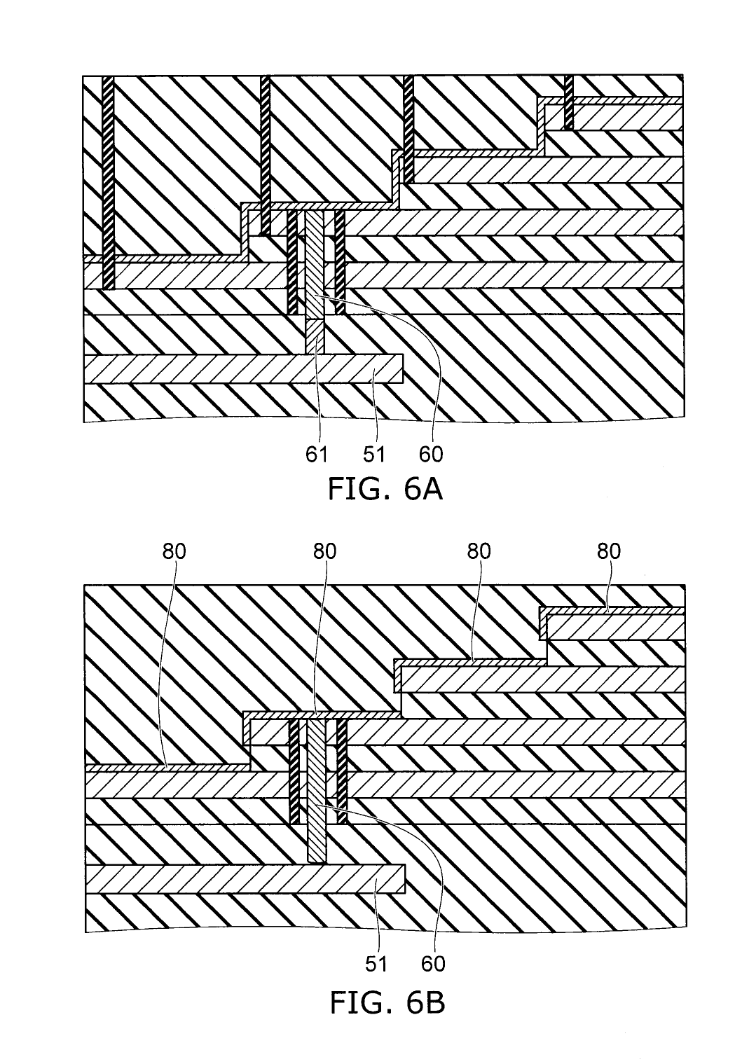

FIG. 6A and FIG. 6B are schematic cross-sectional views showing a nonvolatile semiconductor memory device according to the variation of the embodiment.

For example, as shown in FIG. 6A, another contact electrode 61 may be interposed between the contact electrode 60 and the interconnection layer 51. Accordingly, a margin for position alignment of the contact electrode 60 and the interconnection layer 51 is increased. In addition, a dimension of the contact electrode 60 and a pitch of the interconnection layers 51 can be independently determined.

In addition, as shown in FIG. 6B, the conductive film 80 may not be formed on the insulating layer 42. The conductive film 80 may be selectively formed on the electrode layers 40 by selective chemical vapor deposition (CVD). According to this method, the insulating layer 85 and the process of forming the insulating layer 85 are not necessary.

The effect of the embodiment will be described.

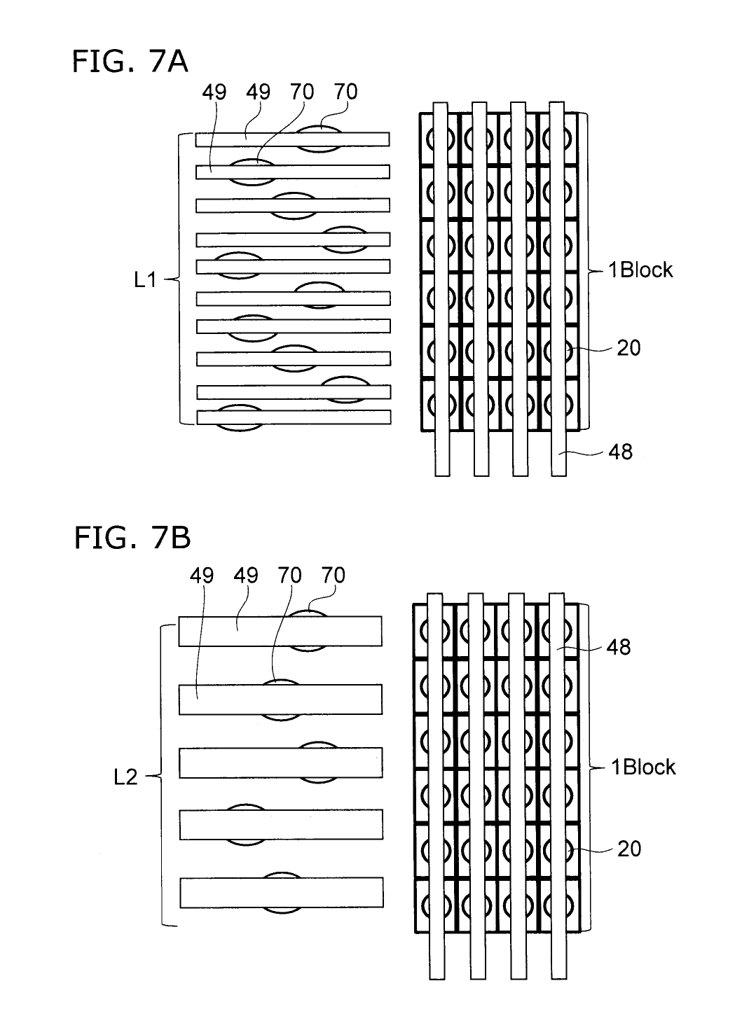

FIG. 7A is a schematic plan view showing layout of interconnections according to a reference example, and FIG. 7B is a schematic plan view showing layout of interconnections according to the embodiment.

Herein, the number of stacked layers of the memory cell array unit in the reference example shown in FIG. 7A is the same as that of the memory cell array unit of the embodiment shown in FIG. 7B. Therefore, the width (1 block) of the memory cell array unit is the same as illustrated in FIGS. 7A and 7B.

In the reference example shown in FIG. 7A, the contact electrode 60 is not provided. Therefore, it is necessary to dispose the interconnection 49, which is electrically connected to each of the plurality of electrode layers 40, in the upper layer of the nonvolatile semiconductor memory device. Accordingly, a process which makes the width of each of the interconnections 49 small and a process which makes the pitch thereof narrow are needed.

As described above, in the micro-patterning technique, as the number of stacked layers in the memory cell array is increased, the lithography margin is decreased so that the patterning is difficult to be performed. For example, the pitch of the interconnections 49 is proportional to a value obtained by dividing the width (1 block) of the memory cell array unit by the number of stacked layers.

In contrast, in the embodiment shown in FIG. 7B, a part of the plurality of electrode layers 40 is connected to the contact electrode 60, and the connection portion of the contact electrode 60 is lead to the multilayer interconnection structure unit under the memory cell array. In addition, the interconnections 49 which are electrically connected to the remaining electrode layers 40 which are not electrically connected to the contact electrode 60 are arranged in the upper layer of the nonvolatile semiconductor memory device.

Therefore, the number of the interconnections 49 arranged in the upper layer of the nonvolatile semiconductor memory device is greatly decreased in comparison with the reference example. Accordingly, in the embodiment, the width of each of the interconnections 49 can be formed to be large and the pitch thereof can be wide in comparison with the reference example. Therefore, the lithography margin in the micro-patterning technique is increased so that the patterning is also easy to be performed.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile semiconductor memory device comprising:
a semiconductor substrate;
a multilayer interconnection structure unit provided on the semiconductor substrate, and the multilayer interconnection structure unit having a plurality of interconnections;
a stacked body provided on the multilayer interconnection structure unit, and each of a plurality of electrode layers and each of a plurality of first insulating layers being alternately arranged in the stacked body;
a channel body layer extending in the stacked body in a stacking direction of the stacked body;
a memory film provided between the channel body layer and each of the electrode layers; and
a contact electrode extending in the stacked body in the stacking direction, and the contact electrode electrically connecting any one of the electrode layers and any one of the interconnection layers.

2. The device according to claim 1, further comprising a second insulating layer provided between a side portion of the contact electrode and the stacked body.

3. The device according to claim 2, wherein the second insulating layer surrounds the contact electrode.

4. The device according to claim 2, wherein the contact electrode is not in contact with the second insulating layer.

5. The device according to claim 1, wherein
each of the electrode layers has an extension portion, and
any of the electrode layers does not exist above the extension portion.

6. The device according to claim 5, wherein an upper end of the contact electrode is in contact with a conductive film provided on the extension portion.

7. The device according to claim 6, wherein the contact electrode is electrically connected to any one of the electrode layers through the conductive film.

8. The device according to claim 6, the conductive film provided on the extension portion of any one of the electrode layers and the conductive film provided on another extension portion adjacent to the extension portion is insulated each other by a third insulating layer.

9. The device according to claim 1, wherein the contact electrode includes polysilicon.

10. The device according to claim 1, wherein another contact electrode is provided between the contact electrode and any one of the interconnection layers.

11. A method for manufacturing a nonvolatile semiconductor memory device, comprising:
preparing a semiconductor substrate, a multilayer interconnection structure unit, and a stacked body, the multilayer interconnection structure unit having a plurality of interconnections provided on the semiconductor substrate, the stacked body being provided on the multilayer interconnection structure unit, and each of a plurality of electrode layers and each of a plurality of first insulating layers are alternately arranged in the stacked body;
forming a connect electrode and a second insulating layer, the connect electrode piercing the stacked body in a stacking direction of the stacked body, the connect electrode being electrically connected to any one of the interconnection layers, and the second insulating layer being provided between a side portion of the contact electrode and the stacked body;
forming a structure, each of the electrode layers having an extension portion, any of the electrode layers not existing above the extension portion, and heights of the contact electrode and the second insulating layer and a height of the extension portion at the contact electrode being aligned in the structure by processing the stacked body into a staircase pattern; and
forming a conductive film on the extension portion at the contact electrode, and an upper end of the contact electrode being in contact with the conductive film.

12. The method according to claim 11, wherein the conductive film is not formed on the first insulating layer and the conductive film is selectively formed on the electrode layer by selective CVD.
